(19) United States
(12) Patent Application Publication
(10) Pub. No.: US 2024/0027654 A1
(43) Pub. Date: Jan. 25, 2024

(54) GLASS LAMINATE WITH AN OUTER GRADIENT LAYER

(71) Applicant: Apple Inc., Cupertino, CA (US)

(72) Inventors: Lijie Bao, San Jose, CA (US); Que Anh S. Nguyen, San Jose, CA (US); Tyler R. Roschuk, San Jose, CA (US); Ralf Hofmann, Soquel, CA (US); Matthew S. Rogers, San Jose, CA (US)

(73) Assignee: Apple Inc., Cupertino, CA (US)

(21) Appl. No.: 18/223,224

(22) Filed: Jul. 18, 2023

Related U.S. Application Data
(60) Provisional application No. 63/391,619, filed on Jul. 22, 2022.

(51) Int. Cl. G02B 1/14; C23C 14/10; C23C 14/06; C23C 14/34; C23C 14/00; C03C 17/34

(52) U.S. Cl. CPC G02B 1/14; C23C 14/10; C23C 14/0676; C23C 14/34; C23C 14/0084; C03C 17/3435; C03C 2218/155; C03C 2217/78

(57) ABSTRACT

An electronic device can include a housing, a display positioned within the housing; and a cover glass disposed over the display and attached to the housing. The cover glass can include a glass sheet; a hard coat layer disposed on the glass sheet, having a hardness greater than a hardness of the glass sheet; and a gradient layer deposited on the hard coat layer and having a composition that transitions from a first composition at the hard coat layer to a second composition at a top surface of the gradient layer. The first composition can be predominantly a composition of the hard coat layer and the second composition is different than the first composition. The second composition can be predominantly SiO2. The hard coat layer can include SiON. The cover glass can include an intermediate gradient layer disposed between the glass sheet and the hard coat layer.

### CROSS-REFERENCES TO OTHER APPLICATIONS

This application claims priority to U.S. provisional patent application Ser. No. 63/391,619, for “Glass Laminate With An Outer Gradient Layer” filed on Jul. 22, 2022 which is hereby incorporated by reference in entirety for all purposes.

### FIELD

The described embodiments relate generally to electronic devices that employ a transparent cover glass disposed over a display screen. The transparent cover glass forms an exterior portion of the enclosure of the electronic device and protects the display screen from damage. More particularly, the present embodiments relate to a cover glass formed from various glass or ceramic materials. The cover glass can have a coating layer that may comprise one or more of silicon dioxide, silicon nitride, or silicon oxynitride.

### BACKGROUND

Many portable electronic devices, such as smart phones and tablet computers, include a touch sensitive display. The display typically includes part of a stack of components that includes a display screen, a touch sensitive layer overlaying the display screen and an outer transparent glass sheet, often referred to as a “cover glass” that protects the display and touch sensitive layer. As the cover glass is a portion of the outer enclosure of the electronic device, the cover glass needs to be strong and resistant to scratches.

The cover glass used for many portable electronic devices is typically made of a chemically-strengthened glass that provides improved fracture resistance to certain drop and impact events as compared to standard glass. The strengthened glass is, however, inherently softer than some other material options, which can lead to scratches formed on the surface of the glass that are detrimental to both user perception and to the reliability of the cover glass, as the scratches can reduce the fracture strength of the glass.

### SUMMARY

Some embodiments of the present disclosure relate to an electronic device comprising a housing and a display positioned within the housing. A cover glass is disposed over the display and is attached to the housing. The cover glass comprises a glass sheet, a hard coat layer disposed on the glass sheet and a gradient layer deposited on the hard coat layer. The hard coat layer has a hardness greater than a hardness of the glass sheet. The gradient layer has a composition that transitions from a first composition at the hard coat layer to a second composition at a top surface of the gradient layer, wherein the first composition is predominantly a composition of the hard coat layer and the second composition is different than the first composition.

In some embodiments the second composition is predominantly SiO₂. In various embodiments the hard coat layer comprises SiON. In some embodiments the gradient layer transitions from the first composition that is predominantly SiON at the hard coat layer to the second composition that is predominantly SiO₂ at the top surface. In various embodiments the electronic device further comprises an intermediate gradient layer disposed between the glass sheet and the hard coat layer.

In some embodiments the intermediate gradient layer transitions from a composition that is predominantly SiO₂ at the glass sheet to a composition that is predominantly SiON at the hard coat layer. In various embodiments the electronic device further comprises an exterior layer that is disposed on the top surface of the gradient layer and has a hardness that is greater than the gradient layer. In some embodiments the exterior layer comprises SiN. In some embodiments the glass sheet comprises SiO₂.

In some embodiments a cover glass comprises a glass sheet and a hard coat layer disposed on the glass sheet, the hard coat layer having a hardness greater than a hardness of the glass sheet. A gradient layer is deposited on the hard coat layer and has a composition that transitions from a first composition at the hard coat layer to a second composition at a top surface of the gradient layer, wherein the first composition is predominantly a composition of the hard coat layer and the second composition is different than the first composition.

In some embodiments the second composition is predominantly SiO₂. In various embodiments the hard coat layer comprises SiON. In some embodiments the gradient layer transitions from the first composition that is predominantly SiON at the hard coat layer to the second composition that is predominantly SiO₂ at the top surface. In various embodiments the cover glass further comprises an intermediate gradient layer disposed between the glass sheet and the hard coat layer. In some embodiments the intermediate gradient layer transitions from a composition that is predominantly SiO₂ at the glass sheet to a composition that is predominantly SiON at the hard coat layer.

In some embodiments a method of forming a transparent substrate comprises providing a glass sheet and depositing a hard coat layer on the glass sheet, the hard coat layer having a hardness greater than a hardness of the glass sheet. A gradient layer is deposited on the hard coat layer wherein the gradient layer has a composition that transitions from a first composition at the hard coat layer to a second composition at a top surface of the gradient layer, wherein the first composition is predominantly a composition of the hard coat layer and the second composition is different than the first composition.

In some embodiments the second composition is predominantly SiO₂. In various embodiments the hard coat layer comprises SiON. In some embodiments the gradient layer transitions from the first composition that is predominantly SiON at the hard coat layer to the second composition that is predominantly SiO₂ at the top surface. In various embodiments the method further comprises depositing an intermediate gradient layer between the glass sheet and the hard coat layer.

To better understand the nature and advantages of the present disclosure, reference should be made to the following description and the accompanying figures. It is to be understood, however, that each of the figures is provided for the purpose of illustration only and is not intended as a definition of the limits of the scope of the present disclosure. Also, as a general rule, and unless it is evident to the contrary from the description, where elements in different figures use identical reference numbers, the elements are generally either identical or at least similar in function or purpose.

### BRIEF DESCRIPTION OF THE DRAWINGS

FIG. 1 illustrates a simplified perspective view of an electronic device 100 that can include a cover glass having an exterior gradient layer according to embodiments of the disclosure;

FIG. 2 illustrate a simplified perspective view of the cover glass illustrated in FIG. 1;

FIG. 3 illustrate a simplified cross-sectional view of the cover glass illustrated in FIGS. 1 and 2, according to some embodiments of the disclosure;

FIG. 4 illustrates steps associated with a method forming a cover glass including an exterior gradient layer, according embodiments of the disclosure;

FIG. 5 illustrates a simplified cross-sectional view of a cover glass including multiple hard coat layers, according to some embodiments of the disclosure;

FIG. 6 illustrates a simplified cross-sectional view of a cover glass including three gradient layers, according to some embodiments of the disclosure;

FIG. 7 illustrates a simplified cross-sectional view of a cover glass including two gradient layers, according to some embodiments of the disclosure;

FIG. 8 illustrates a simplified cross-sectional view of a cover glass including multiple hard coat and gradient layers with a terminal hard coat layer, according to some embodiments of the disclosure;

FIG. 9 illustrates a simplified cross-sectional view of a cover glass including multiple hard coat and gradient layers with a terminal hard coat layer, according to some embodiments of the disclosure; and

FIG. 10 illustrates a simplified cross-sectional view of a cover glass including multiple hard coat and gradient layers with a terminal hard coat layer, according to some embodiments of the disclosure.

### DETAILED DESCRIPTION

Electronic devices often use a cover glass to protect a touch-sensitive display from damage. The cover glass may have a top layer that forms an anti-reflective coating to improve the appearance and usability of the electronic device in lighted areas. As the cover glass forms an exterior portion of the enclosure of the electronic device it is subject to mechanical damage and scratching. Conventional anti-reflective coatings are typically made from sequential discrete layers of materials terminated in a relatively soft material making them prone to scratches. The scratches can induce delamination at the interfaces of the discrete layers resulting in failure of the cover glass. The present technology can overcome these issues by forming an antireflective coating using a gradient layer that gradually transitions from one chemical composition to another.

In one example a cover glass includes a silicon oxynitride scratch resistant coating that is terminated with a gradient layer that gradually transitions from a composition of silicon oxynitride at the silicon oxynitride layer to a composition of silicon dioxide at a top surface of the gradient layer. The gradual transition from one chemical composition to another throughout the gradient layer removes the discrete material interfaces making the gradient layer more resistant to delamination. Also, because at least a portion of the gradient layer comprises silicon oxynitride the gradient layer has a higher hardness than traditional antireflective coatings that are terminated in a discrete layer of silicon dioxide. The gradient layer can be designed in combination with the other layers to reduce reflectance of the cover glass via destructive interference.

In order to better appreciate the features and aspects of cover glasses with gradient top layers for electronic devices according to the present disclosure, further context for the disclosure is provided in the following section by discussing one particular implementation of an electronic device according to embodiments of the present disclosure. These embodiments are for example only and other embodiments can be employed in other electronic devices such as, but not limited to computers, watches, media players and other devices.

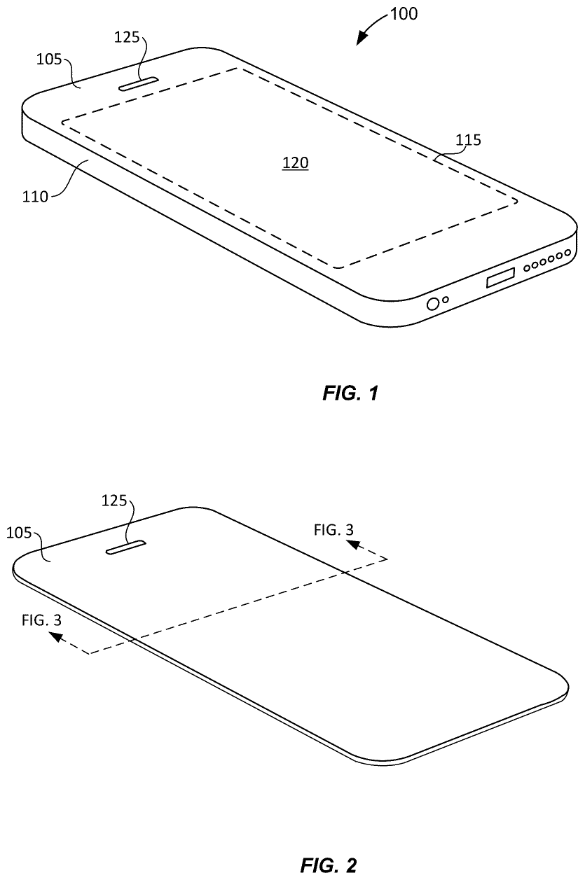

FIG. 1 depicts a simplified perspective view of an electronic device 100 that can include a cover glass according to embodiments of the disclosure. As shown in FIG. 1, electronic device 100, which in this example is a smart phone, includes a cover glass 105 attached to a housing 110 and positioned at least partially over display 115. Cover glass 105 and housing 110 combine to provide an enclosure that houses the various electronic components of electronic device 100 including a processor, communication circuitry, display 115, camera and battery, among other components (not all shown in FIG. 1). Cover glass 105 is transparent and includes a central area 120 that corresponds to display 115, and outside the central display area includes a cut out 125 for a receiver. In some embodiments cover glass 105 provides protection for display 115 and can also form a continuous transparent surface of the enclosure for electronic device 100.

FIG. 2 is a simplified perspective view of the cover glass illustrated in FIG. 1. As shown in FIG. 2, cover glass 105 is removed from housing 110 (see FIG. 1). While not visible in FIG. 2, in some embodiments cover glass 105 can include a silicon dioxide layer with a scratch resistant layer terminated in an antireflective gradient layer, as discussed in more detail below.

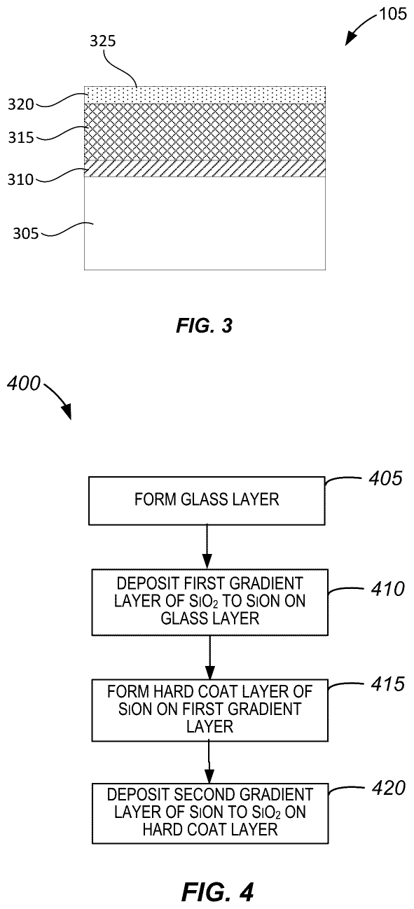

FIG. 3 is a simplified partial cross-sectional view of the cover glass illustrated in FIGS. 1 and 2, according to embodiments of the disclosure. As shown in FIG. 3, cover glass 105 includes a glass layer 305 that may comprise silicon dioxide (SiO₂), including chemically strengthened glass, or other suitable material. A first gradient layer 310 can be formed on glass layer 305. A hard coat layer 315 can be formed on first gradient layer 310 and can comprise silicon oxynitride (SiON) or other suitable material. In various embodiments, the first gradient layer 310 transitions from the first composition that is predominantly SiON at the hard coat layer 315 to the second composition that is predominantly SiO₂. For example, first gradient layer 310 can gradually transition from a composition that is predominantly SiO₂ at glass layer 305 to a composition that is predominantly SiON at hard coat layer 315. The slope and thickness of first gradient layer 310 can be controlled to limit the amount of SiO₂ at the interface between the layers. A second gradient layer 320 can be formed on hard coat layer 315. Second gradient layer 320 can gradually transition from a composition that is predominantly SiON at hard coat layer 315 to a composition that is predominantly SiO₂ at a top surface 325 of the second gradient layer. In various embodiments, second gradient layer 320 can have a lower refractive index than the bulk SiON used for hardcoat layer 315 in order to have an anti-reflective effect. In various embodiments, the refractive index of bulk SiON is between 1.70 and 1.76 and in some embodiments bulk SiON hardcoat layer 315 terminates in a composition of pure SiN with a refractive index that can be between 1.9 and 2.1. In such embodiments second gradient layer 320 may terminate in SiO₂ or may include a gradient to a lower index of refraction SiON. The refractive index of terminated SiON at very top layer next to air can be between 1.5 and 1.6. The differentiation of the various SiON layers can be high hardness, high refractive index versus moderate hardness, and moderate refractive index. In various embodiments, a coating design can have a mix of gradient layers and discrete layers.

In various embodiments second gradient layer 320 can form at least a portion of an antireflective coating for cover glass 105 and can have a hardness that is greater than glass layer 305. In some embodiments second gradient layer 320 can have a nanohardness between 900-2000, between 1200-1800 or between 1400-1500. In some embodiments glass layer 305 can have a nanohardness between 580-815 kilogram-force per square millimeter (kgf/mm²) using the Vickers hardness scale. In various embodiments a reflectance of cover glass 105 can be between 3-10%, between 5-8% or between 6-7%. In various embodiments, the 2.5% reflectance can be achieved using an anti-smudge/oleophobic coat at the top surface. An oleophobic coating may be added on top of the gradient layer. In some embodiments hard coat layer 315 can have a hardness that is greater than glass layer 305 and can be made from any suitable material including but not limited to silicon nitride, aluminum oxide, aluminum nitride, titanium nitride or zirconium dioxide. In various embodiments, build SiON hardness is approximately 1500, second gradient layer 320 hardness can be lower than 1500. In various embodiments hard coat layer 315 can have a thickness between 100-3000 nm, between 500-2000 nm, between 900-1800 nm or between 1700-1900 nm.

In some embodiments first gradient layer 310 can transition from a composition that is predominantly SiO₂ at glass layer 305 to a composition that is substantially similar to hard coat layer 315 at the hard coat layer. First gradient layer 310 can have a thickness between 25-2000 nm, between 100-1000 nm between 200-400 nm or between 180-220 nm.

In some embodiments second gradient layer 320 can transition from a composition that is substantially similar to a composition of hard coat layer 315 at the hard coat layer to a composition that is different at top surface 325. A few additional examples of such transitions are discussed in greater detail below, however this disclosure is not limited to the compositions and transitions disclosed herein. Second gradient layer 320 can have a thickness between 25-2000 nm, between 100-1000 nm between 80-225 nm or between 75-125 nm.

In some embodiments an exterior layer (not shown) can be formed on second gradient layer 320 and can have a hardness greater than glass layer 305. In various embodiments the exterior layer can be made from, but is not limited to silicon nitride, diamond-like carbon, aluminum oxide, aluminum nitride, titanium nitride or zirconium dioxide. The exterior layer can have a thickness between 1-200 nm, between 5-100 nm or between 10-20 nm.

FIG. 4 illustrates steps associated with a method of forming a cover glass with an outer gradient layer according to embodiments of the disclosure. As shown in FIG. 4, method 400 includes forming a glass layer (step 405) using any appropriate manufacturing technique. In some embodiments the glass layer is formed from SiO₂ and may include a chemically strengthened glass material.

In step 410 the first gradient layer is deposited on the glass layer. The first gradient layer can be formed on one surface of the glass layer. In some embodiments the first gradient layer can be deposited using a physical vapor deposition (PVD) sputtering process in which a target containing, for example silicon, is positioned within the PVD chamber and the composition of the gradient layer can be varied from SiO₂ at the glass layer to SiON at the top surface by varying a partial pressure of oxygen and nitrogen, among other parameters, during the deposition process. The transition from SiO₂ to SiON within the first gradient layer is for example only and as appreciated by one of ordinary skill having the benefit of this disclosure the first gradient layer can transition from a first composition that is substantially similar to a composition of the glass layer at the glass layer to a second composition at the hard coat layer that is substantially similar to a composition of the hard coat layer. In some embodiments the gradual transition in composition is substantially linear throughout the thickness of the gradient layer while in other embodiments the transition in composition is substantially non-linear. Other deposition techniques than PVD can be used to form the first gradient layer and are within the scope of this disclosure. In some embodiments, the first gradient layer can be eliminated and the hard coat layer can be deposited directly on the glass layer.

In step 415 a hard coat layer is deposited on the first gradient layer. In some embodiments the hard coat layer can be made from, but is not limited to silicon oxynitride, silicon nitride, aluminum oxide, aluminum nitride, titanium nitride or zirconium dioxide. The hard coat layer can have a higher hardness than the glass layer to protect the glass layer from scratches and/or mechanical damage. In some embodiments the hard coat layer can be deposited using a physical vapor deposition (PVD) or other suitable process.

In step 420 the second gradient layer is deposited on the hard coat layer. In some embodiments the second gradient layer can be deposited using a physical vapor deposition (PVD) sputtering process in which a target containing, for example silicon, is positioned within the PVD chamber and the composition of the gradient layer can be varied from SiON at the hard coat layer to SiO₂ at the top surface by varying a partial pressure of oxygen and nitrogen, among other parameters, during the deposition process. The transition from SiON to SiO₂ within the second gradient layer is for example only and as appreciated by one of ordinary skill having the benefit of this disclosure the second gradient layer can transition from a first composition that is substantially similar to a composition of the hard coat layer at the hard coat layer to any other suitable composition at the top surface. In some embodiments the gradual transition in composition is substantially linear throughout the thickness of the gradient layer while in other embodiments the transition in composition is substantially non-linear. Other deposition techniques than PVD can be used to form the second gradient layer and are within the scope of this disclosure. In some embodiments the first gradient layer can be designed to have destructive interference with one or more other layers in the cover glass to reduce reflection within the cover glass. In various embodiments, the termination of the silicon oxynitride (SiON) layer can have lower refractive index and lower hardness than the build SiON used for the hardcoat. The differentiation of the various SiON layer can be high hardness, high refractive index versus moderate hardness, and moderate refractive index.

In some embodiments an optional outer layer may be deposited on the top surface of the second gradient layer and may have a hardness that is greater than a hardness of the glass layer. In various embodiments a composition of the outer layer may be, but is not limited to, silicon nitride, diamond-like carbon, aluminum oxide, aluminum nitride, titanium nitride or zirconium dioxide.

As defined herein, the terms silicon oxide and silicon dioxide can be used interchangeably with all forms of oxygen including O, O₂, and O₃ (e.g., silicon dioxide can be interchanged with SiO or with SiO₃).

It will be appreciated that method 400 is illustrative and that variations and modifications are possible. Steps described as sequential may be executed in parallel, order of steps may be varied, and steps may be modified, combined, added, or omitted.

Although electronic device 100 (see FIG. 1) is described and illustrated as one particular electronic device, embodiments of the disclosure are suitable for use with a multiplicity of electronic devices. For example, any device that receives or transmits audio, video or data signals can be used with embodiments of the disclosure. In some instances, embodiments of the disclosure are particularly well suited for use with portable electronic media devices because of their use of transparent display screens. As used herein, an electronic media device includes any device with at least one electronic component that can be used to present human-perceivable media. Such devices can include, for example, portable music players (e.g., MP3 devices and Apple's iPod devices), portable video players (e.g., portable DVD players), cellular telephones (e.g., smart telephones such as Apple's iPhone devices), video cameras, digital still cameras, projection systems (e.g., holographic projection systems), gaming systems, PDAs, as well as tablet (e.g., Apple's iPad devices), laptop or other mobile computers. Some of these devices can be configured to provide audio, video or other data or sensory output.

For simplicity, various internal components, such as the control circuitry, graphics circuitry, bus, memory, storage device and other components of electronic device 100 (see FIG. 1) are not shown in the figures.

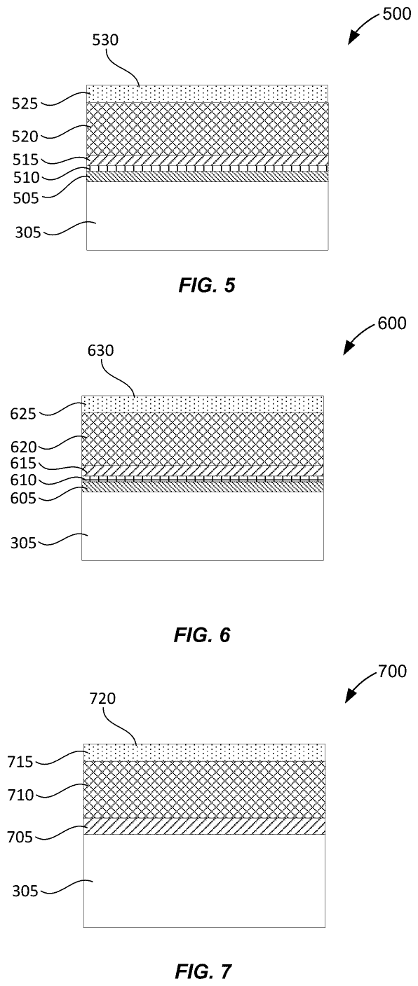

FIG. 5 is a simplified partial cross-sectional view of another embodiment of the cover glass illustrated in FIGS. 1 and 2, according to embodiments of the disclosure. Cover glass 500 may include any of the components, features, or characteristics of any of the cover glass structures previously described with like numbers referring to like items, and the cover glass may be included in any of the electronic devices as previously discussed. As shown in FIG. 5, cover glass 500 includes a glass layer 305 that may comprise silicon dioxide (SiO₂), including chemically strengthened glass, or other suitable material. A first gradient layer 505 can be formed on glass layer 305. A first hard coat layer 510 can be formed on first gradient layer 505 and can comprise silicon oxynitride (SiON) or other suitable material.

First gradient layer 505 can gradually transition from a composition that is predominantly SiO₂ at glass layer 305 to a composition that is predominantly SiON at first hard coat layer 510. A second gradient layer 515 can be formed on first hard coat layer 510. Second gradient layer 515 can gradually transition from a composition that is predominantly SiON at first hard coat layer 510 to a composition that is predominantly high nitrogen content SiON. A second hard coat layer 520 can be deposited on second gradient layer 515 and can comprise high nitrogen content SiON. A third gradient layer 525 can be deposited on second hard coat layer 520. Third gradient layer 525 can gradually transition from a composition that is predominantly high nitrogen content SiON at second hard coat layer 520 to a composition that is predominantly low nitrogen content SiON at a top surface 530.

The gradual transition from one chemical composition to another throughout the gradient layers removes the discrete material interfaces making the gradient layers more resistant to delamination. Also, because at least a portion of the third gradient layer comprises silicon oxynitride the third gradient layer has a higher hardness than traditional antireflective coatings that are terminated in a discrete layer of silicon dioxide. The gradient layers can be designed in combination with the other layers to reduce reflectance of the cover glass via destructive interference.

In some embodiments an exterior layer (not shown) can be formed on third gradient layer 525 and can have a hardness greater than glass layer 305. In various embodiments the exterior layer can be made from, but is not limited to silicon nitride, diamond-like carbon, aluminum oxide, aluminum nitride, titanium nitride or zirconium dioxide.

FIG. 6 is a simplified partial cross-sectional view of another embodiment of the cover glass illustrated in FIGS. 1 and 2, according to embodiments of the disclosure. Cover glass 600 may include any of the components, features, or characteristics of any of the cover glass structures previously described with like numbers referring to like items, and the cover glass may be included in any of the electronic devices as previously discussed. As shown in FIG. 6, cover glass 600 includes a glass layer 305 that may comprise silicon dioxide (SiO₂), including chemically strengthened glass, or other suitable material. A first gradient layer 605 can be formed on glass layer 305. A first hard coat layer 610 can be formed on first gradient layer 605 and can comprise silicon oxynitride (SiON) or other suitable material.

First gradient layer 605 can gradually transition from a composition that is predominantly SiO₂ at glass layer 305 to a composition that is predominantly SiON at first hard coat layer 610. A second gradient layer 615 can be formed on first hard coat layer 610. Second gradient layer 615 can gradually transition from a composition that is predominantly SiON at first hard coat layer 610 to a composition that is predominantly SiN. A second hard coat layer 620 can be deposited on second gradient layer 615 and can comprise SiN. A third gradient layer 625 can be deposited on second hard coat layer 620. Third gradient layer 625 can gradually transition from a composition that is predominantly SiN at second hard coat layer 620 to a composition that is predominantly SiON at a top surface 630.

The gradual transition from one chemical composition to another throughout the gradient layers removes the discrete material interfaces making the gradient layers more resistant to delamination. Also, because at least a portion of the third gradient layer comprises silicon nitride the third gradient layer has a higher hardness than traditional antireflective coatings that are terminated in a discrete layer of silicon dioxide. The gradient layers can be designed in combination with the other layers to reduce reflectance of the cover glass via destructive interference.

In some embodiments an exterior layer (not shown) can be formed on third gradient layer 625 and can have a hardness greater than glass layer 305. In various embodiments the exterior layer can be made from, but is not limited to silicon nitride, diamond-like carbon, aluminum oxide, aluminum nitride, titanium nitride or zirconium dioxide.

FIG. 7 is a simplified partial cross-sectional view of another embodiment of the cover glass illustrated in FIGS. 1 and 2, according to embodiments of the disclosure. Cover glass 700 may include any of the components, features, or characteristics of any of the cover glass structures previously described with like numbers referring to like items, and the cover glass may be included in any of the electronic devices as previously discussed. As shown in FIG. 7, cover glass 700 includes a glass layer 305 that may comprise silicon dioxide (SiO₂), including chemically strengthened glass, or other suitable material. A first gradient layer 705 can be formed on glass layer 305. A first hard coat layer 710 can be formed on first gradient layer 705 and can comprise silicon oxynitride (SiON) or other suitable material.

First gradient layer 705 can gradually transition from a composition that is predominantly SiO₂ at glass layer 305 to a composition that is predominantly SiON at first hard coat layer 710. A second gradient layer 715 can be formed on first hard coat layer 710. Second gradient layer 715 can gradually transition from a composition that is predominantly SiON at first hard coat layer 710 to a composition that is predominantly high nitrogen content SiON at top surface 720.

The gradual transition from one chemical composition to another throughout the gradient layers removes the discrete material interfaces making the gradient layers more resistant to delamination. Also, because at least a portion of the second gradient layer comprises silicon oxynitride the second gradient layer has a higher hardness than traditional antireflective coatings that are terminated in a discrete layer of silicon dioxide. The gradient layers can be designed in combination with the other layers to reduce reflectance of the cover glass via destructive interference.

In some embodiments an exterior layer (not shown) can be formed on second gradient layer 715 and can have a hardness greater than glass layer 305. In various embodiments the exterior layer can be made from, but is not limited to silicon nitride, diamond-like carbon, aluminum oxide, aluminum nitride, titanium nitride or zirconium dioxide.

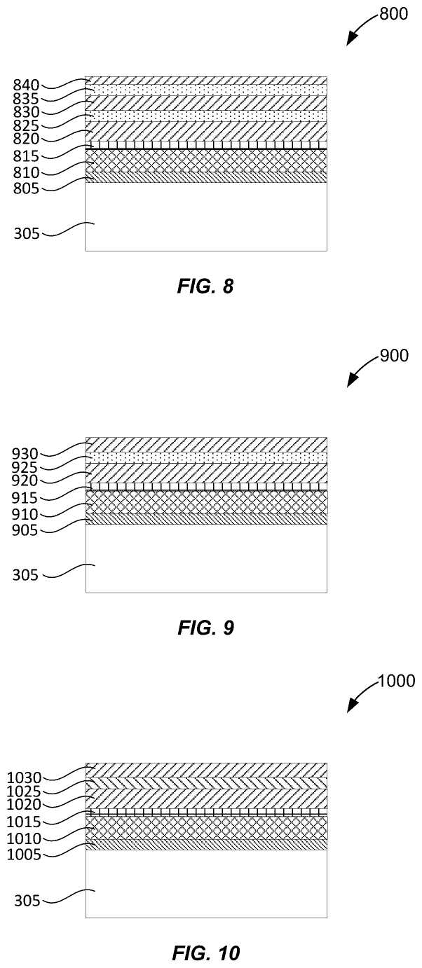

FIG. 8 is a simplified partial cross-sectional view of another embodiment of the cover glass illustrated in FIGS. 1 and 2, according to embodiments of the disclosure. Cover glass 800 may include any of the components, features, or characteristics of any of the cover glass structures previously described with like numbers referring to like items, and the cover glass may be included in any of the electronic devices as previously discussed. As shown in FIG. 8, cover glass 800 includes a glass layer 305 that may comprise silicon dioxide (SiO₂), including chemically strengthened glass, or other suitable material. A first gradient layer 805 can be formed on glass layer 305. A first hard coat layer 810 can be formed on first gradient layer 805 and can comprise silicon oxynitride (SiON) or other suitable material.

First gradient layer 805 can gradually transition from a composition that is predominantly SiO₂ at glass layer 305 to a composition that is predominantly SiN at first hard coat layer 810. A second gradient layer 815 can be formed on first hard coat layer 810. Second gradient layer 815 can gradually transition from a composition that is predominantly SiON at first hard coat layer 810 to a composition that is predominantly SiN. A second hard coat layer 820 can be deposited on second gradient layer 815 and can comprise SiN. In various embodiments, a first intermediate layer 825 comprising SiO₂ can be formed on second hard coat layer 820. A third hard coat layer 830 can be deposited on first intermediate layer 825 and can comprise SiN. A second intermediate layer 835 comprising SiO₂ can be formed on third hard coat layer 830. A fourth hard coat layer 840 can be deposited on second intermediate layer 835 and can comprise SiN.

The gradual transition from one chemical composition to another throughout the gradient layers removes the discrete material interfaces making the gradient layers more resistant to delamination. The gradient layers can be designed in combination with the other layers to reduce reflectance of the cover glass via destructive interference.

In some embodiments fourth hard coat layer 840 can be made from, but is not limited to silicon nitride, diamond-like carbon, aluminum oxide, aluminum nitride, titanium nitride or zirconium dioxide.

FIG. 9 is a simplified partial cross-sectional view of another embodiment of the cover glass illustrated in FIGS. 1 and 2, according to embodiments of the disclosure. Cover glass 900 may include any of the components, features, or characteristics of any of the cover glass structures previously described with like numbers referring to like items, and the cover glass may be included in any of the electronic devices as previously discussed. As shown in FIG. 9, cover glass 900 includes a glass layer 305 that may comprise silicon dioxide (SiO₂), including chemically strengthened glass, or other suitable material. A first gradient layer 905 can be formed on glass layer 305. A first hard coat layer 910 can be formed on first gradient layer 905 and can comprise silicon oxynitride (SiON) or other suitable material.

First gradient layer 905 can gradually transition from a composition that is predominantly SiO₂ at glass layer 305 to a composition that is predominantly SiON at first hard coat layer 910. A second gradient layer 915 can be formed on first hard coat layer 910. Second gradient layer 915 can gradually transition from a composition that is predominantly SiON at first hard coat layer 910 to a composition that is predominantly SiN. A second hard coat layer 920 can be deposited on second gradient layer 915 and can comprise SiN. A first intermediate layer 925 comprising SiO₂ can be formed on second hard coat layer 920. A third hard coat layer 930 can be deposited on first intermediate layer 925 and can comprise SiN.

The gradual transition from one chemical composition to another throughout the gradient layers removes the discrete material interfaces making the gradient layers more resistant to delamination. The gradient layers can be designed in combination with the other layers to reduce reflectance of the cover glass via destructive interference.

In some embodiments third hard coat layer 930 can be made from, but is not limited to silicon nitride, diamond-like carbon, aluminum oxide, aluminum nitride, titanium nitride or zirconium dioxide.

FIG. 10 is a simplified partial cross-sectional view of another embodiment of the cover glass illustrated in FIGS. 1 and 2, according to embodiments of the disclosure. Cover glass 1000 may include any of the components, features, or characteristics of any of the cover glass structures previously described with like numbers referring to like items, and the cover glass may be included in any of the electronic devices as previously discussed. As shown in FIG. 10, cover glass 1000 includes a glass layer 305 that may comprise silicon dioxide (SiO₂), including chemically strengthened glass, or other suitable material. A first gradient layer 1005 can be formed on glass layer 305. A first hard coat layer 1010 can be formed on first gradient layer 1005 and can comprise silicon oxynitride (SiON) or other suitable material.

First gradient layer 1005 can gradually transition from a composition that is predominantly SiO₂ at glass layer 310 to a composition that is predominantly SiON at first hard coat layer 1010. A second gradient layer 1015 can be formed on first hard coat layer 1010. Second gradient layer 1015 can gradually transition from a composition that is predominantly SiON at first hard coat layer 1010 to a composition that is predominantly SiN. A second hard coat layer 1020 can be deposited on second gradient layer 1015 and can comprise SiN. A third gradient layer 1025 can be formed on second hard coat layer 1020. Third gradient layer 1025 can gradually transition from a composition that is predominantly SiN at second hard coat layer 1020 to a composition that is predominantly low nitrogen SiON. A third hard coat layer 1030 can be deposited on third gradient layer 1025 and can comprise SiN.

The gradual transition from one chemical composition to another throughout the gradient layers removes the discrete material interfaces making the gradient layers more resistant to delamination. The gradient layers can be designed in combination with the other layers to reduce reflectance of the cover glass via destructive interference.

In some embodiments third hard coat layer 1030 can be made from, but is not limited to silicon nitride, diamond-like carbon, aluminum oxide, aluminum nitride, titanium nitride or zirconium dioxide. In various embodiments, a laminate structure can include a glass layer and one or more layers disposed deposited on the glass layer.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In some implementations, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

What is claimed is:

1. An electronic device comprising:
a housing;
a display positioned within the housing; and
a cover glass disposed over the display and attached to the housing, the cover glass comprising:
a glass sheet;
a hard coat layer disposed on the glass sheet, the hard coat layer having a hardness greater than a hardness of the glass sheet; and
a gradient layer deposited on the hard coat layer and having a composition that transitions from a first composition at the hard coat layer to a second composition at a top surface of the gradient layer, wherein the first composition is predominantly a composition of the hard coat layer and the second composition is different than the first composition.

2. The electronic device of claim 1 wherein the second composition is predominantly SiO₂.

3. The electronic device of claim 1 wherein the hard coat layer comprises SiON.

4. The electronic device of claim 3 wherein the gradient layer transitions from the first composition that is predominantly SiON at the hard coat layer to the second composition that is predominantly SiO₂ at the top surface.

5. The electronic device of claim 1 further comprising an intermediate gradient layer disposed between the glass sheet and the hard coat layer.

6. The electronic device of claim 5 wherein the intermediate gradient layer transitions from a composition that is predominantly SiO₂ at the glass sheet to a composition that is predominantly SiON at the hard coat layer.

7. The electronic device of claim 1 further comprising an exterior layer that is disposed on the top surface of the gradient layer and has a hardness that is greater than the gradient layer.

8. The electronic device of claim 7 wherein the exterior layer comprises SiN.

9. The electronic device of claim 1 wherein the glass sheet comprises SiO₂.

10. A cover glass comprising:
a glass sheet;
a hard coat layer disposed on the glass sheet, the hard coat layer having a hardness greater than a hardness of the glass sheet; and
a gradient layer deposited on the hard coat layer and having a composition that transitions from a first composition at the hard coat layer to a second composition at a top surface of the gradient layer, wherein the first composition is predominantly a composition of the hard coat layer and the second composition is different than the first composition.

11. The cover glass of claim 10 wherein the second composition is predominantly SiO₂.

12. The cover glass of claim 10 wherein the hard coat layer comprises SiON.

13. The cover glass of claim 12 wherein the gradient layer transitions from the first composition that is predominantly SiON at the hard coat layer to the second composition that is predominantly SiO₂ at the top surface.

14. The cover glass of claim 10 further comprising an intermediate gradient layer disposed between the glass sheet and the hard coat layer.

15. The cover glass of claim 14 wherein the intermediate gradient layer transitions from a composition that is predominantly SiO₂ at the glass sheet to a composition that is predominantly SiON at the hard coat layer.

16. A method of forming a transparent substrate, the method comprising:
providing a glass sheet;
depositing a hard coat layer on the glass sheet, the hard coat layer having a hardness greater than a hardness of the glass sheet; and
depositing a gradient layer on the hard coat layer wherein the gradient layer has a composition that transitions from a first composition at the hard coat layer to a second composition at a top surface of the gradient layer, wherein the first composition is predominantly a composition of the hard coat layer and the second composition is different than the first composition.

17. The method of claim 16 wherein the second composition is predominantly SiO₂.

18. The method of claim 16 wherein the hard coat layer comprises SiON.

19. The method of claim 18 wherein the gradient layer transitions from the first composition that is predominantly SiON at the hard coat layer to the second composition that is predominantly SiO₂ at the top surface.

20. The method of claim 16 further comprising depositing an intermediate gradient layer between the glass sheet and the hard coat layer.
